(19) United States
(12) Patent Application Publication
(10) Pub. No.: US 2025/0048735 A1
(43) Pub. Date: Feb. 6, 2025

(54) DISPLAY DEVICE AND METHOD OF MANUFACTURING DISPLAY DEVICE

(71) Applicant: Samsung Display Co., Ltd., Yongin-Si (KR)

(72) Inventors: Sung Jun KIM, Yongin-si (KR); Byoung Kwon CHOO, Yongin-si (KR); Seung Bae KANG, Yongin-si (KR); Sung Hoon MOON, Yongin-si (KR)

(21) Appl. No.: 18/667,362

(22) Filed: May 17, 2024

(30) Foreign Application Priority Data
Jul. 31, 2023 (KR) 10-2023-0099857

(51) Int. Cl. H01L 27/12

(52) U.S. Cl. CPC H01L 27/1248; H01L 27/1259

(57) ABSTRACT

According to an embodiment of the disclosure, a display device may include an active layer, a gate electrode disposed on the active layer, a first insulating layer disposed on the gate electrode, entirely covering the gate electrode, and including a flat surface, and a second insulating layer disposed on the first insulating layer and including a flat surface, and the first insulating layer and the second insulating layer may include inorganic materials different from each other.

This application claims priority to Korean Patent Application No. 10-2023-0099857, filed on, Jul. 31, 2023, and all the benefits accruing therefrom under 35 U.S.C. § 119, the content of which in its entirety is herein incorporated by reference.

### BACKGROUND

### 1. Field

The disclosure relates to a display device and a method of manufacturing the display device.

### 2. Description of the Related Art

A display device may include a pixel circuit layer including a pixel circuit. The pixel circuit may include a semiconductor layer and electrodes. The semiconductor layers and the electrodes may be electrically connected to each other through a contact hole structure passing through insulating layers included in the pixel circuit layer.

When a thickness of the pixel circuit layer is increased, an etching depth for forming the contact hole structure may be increased. In this case, properly forming the contact hole structure may be difficult. For example, when the etching depth for forming the contact hole structure is increased, applying an etching process to an intended area may be difficult.

Accordingly, research for reducing the etching depth for forming the contact hole structure is being conducted.

### SUMMARY

A feature of the disclosure is to provide a display device and a method of manufacturing the display device capable of reducing an etching depth for forming a contact hole structure.

According to an embodiment of the disclosure, a display device may include an active layer, a gate electrode disposed on the active layer, a first insulating layer disposed on the gate electrode, entirely covering the gate electrode, and including a flat surface, and a second insulating layer disposed on the first insulating layer and including a flat surface. The first insulating layer and the second insulating layer may include inorganic materials different from each other.

According to an embodiment, the active layer and the gate electrode may be spaced apart from each other. The display device may further include a first gate insulating layer and a second gate insulating layer disposed on the active layer. The gate electrode may include a first gate electrode disposed on the first gate insulating layer and a second gate electrode disposed on the second gate insulating layer.

According to an embodiment, the flat surface of the first insulating layer may not have a step difference.

According to an embodiment, the flat surface of the first insulating layer may face the second insulating layer.

According to an embodiment, the first insulating layer may be directly disposed on the second gate electrode.

According to an embodiment, the flat surface of the first insulating layer does not contact the second gate electrode.

According to an embodiment, the first insulating layer may include silicon oxide, and the second insulating layer may include silicon nitride.

According to an embodiment, the display device may further include an interlayer conductive layer disposed on the second insulating layer, and one surface and another surface of the interlayer conductive layer may be flat.

According to an embodiment, the interlayer conductive layer may include a first layer, a second layer disposed on the first layer, and a third layer disposed on the second layer, and the first layer may contact the second insulating layer.

According to an embodiment, the first layer and the third layer may include a same material, the second layer may include a material different from the material of the first layer and the third layer, and the second layer may include aluminum.

According to an embodiment of the disclosure, a method of manufacturing a display device may include patterning an active layer on a base layer, patterning a gate electrode on the active layer, depositing a pre-polishing insulating layer on the gate electrode, polishing the pre-polishing insulating layer to form a first insulating portion, and forming a second insulating portion on the first insulating portion. The first insulating portion and the second insulating portion may form a first insulating layer. The patterning the gate electrode on the active layer may include forming a first gate electrode, and forming a second gate electrode on the first gate electrode. The first gate electrode and the second gate electrode may be spaced apart from the active layer. In the depositing the pre-polishing insulating layer on the gate electrode, the pre-polishing insulating layer may contact the second gate electrode.

According to an embodiment, in the polishing the pre-polishing insulating layer to form the first insulating portion, the pre-polishing insulating layer may be polished using a polishing device using a slurry, and the first insulating portion may form a flat polish surface.

According to an embodiment, the method may further include forming a second insulating layer on the second insulating portion, and forming an interlayer conductive layer on the second insulating layer. In the forming the interlayer conductive layer on the second insulating layer, the interlayer conductive layer may be etched by an etching solution including a chlorine radical.

According to an embodiment, in the depositing the pre-polishing insulating layer on the gate electrode, the pre-polishing insulating layer may be deposited to have a thickness of 5500 Å to 8250 Å.

According to an embodiment, in the polishing the pre-polishing insulating layer to form the first insulating portion, the pre-polishing insulating layer may be polished to form the flat polish surface, and the flat polish surface may be disposed on a plane different from one surface of the second gate electrode.

According to an embodiment, the slurry may include silica, and the pre-polishing insulating layer may be polished during a predetermined polishing time.

According to an embodiment, in the polishing the pre-polishing insulating layer to form the first insulating portion, the first insulating portion may be polished to have a thickness of 500 Å to 1000 Å in an area overlapping the first gate electrode and the second gate electrode.

According to an embodiment, in the polishing the pre-polishing insulating layer to form the first insulating portion, the pre-polishing insulating layer may be polished to form the flat polish surface, and the flat polish surface may be disposed on a same plane as one surface of the second gate electrode.

The slurry may include ceria.

The first insulating layer may include silicon oxide, and the slurry may have a selectivity of 1:30 to 1:50 based on the second gate electrode: the silicon oxide.

According to an embodiment of the disclosure, a display device and a method of manufacturing the display device capable of reducing an etching depth for forming a contact hole structure may be provided.

### BRIEF DESCRIPTION OF THE DRAWINGS

FIG. 1 is a plan view schematically illustrating a display device according to an embodiment.

FIG. 2 is a cross-sectional view schematically illustrating a display device according to an embodiment.

FIG. 3 is a schematic cross-sectional view illustrating a display device according to a first embodiment.

FIG. 4 is a schematic cross-sectional view illustrating a disposition relationship between an interlayer conductive layer and a second insulating layer.

FIG. 5 is a flowchart illustrating a method of manufacturing a display device according to an embodiment.

FIGS. 6, 7, 8, 9, 10, 11, 12, and 13 are schematic cross-sectional views for each manufacturing process operation of the display device according to the first embodiment.

FIG. 14 is a schematic cross-sectional view of a display device according to a second embodiment.

FIGS. 15, 16, and 17 are schematic cross-sectional views for each manufacturing process operation of the display device according to the second embodiment.

### DETAILED DESCRIPTION OF THE EMBODIMENTS

The disclosure may be modified in various manners and have various forms. Therefore, specific embodiments will be illustrated in the drawings and will be described in detail in the specification. However, it should be understood that the disclosure is not intended to be limited to the disclosed specific forms, and the disclosure includes all modifications, equivalents, and substitutions within the spirit and technical scope of the disclosure.

Terms of “first”, “second”, and the like may be used to describe various components, but the components should not be limited by the terms. The terms are used only for the purpose of distinguishing one component from another component. For example, without departing from the scope of the disclosure, a first component may be referred to as a second component, and similarly, a second component may also be referred to as a first component. In the following description, the singular expressions include plural expressions unless the context clearly dictates otherwise.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a layer, an area, a plate, or the like is referred to as being “on” another portion, it includes not only a case where the portion is “directly on” another portion, but also a case where there is further another portion between the portion and the other portion. In addition, in the present specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and the other portion.

The disclosure relates to a display device and a method of manufacturing the display device. Hereinafter, a display device and a method of manufacturing the display device according to an embodiment are described with reference to the accompanying drawings.

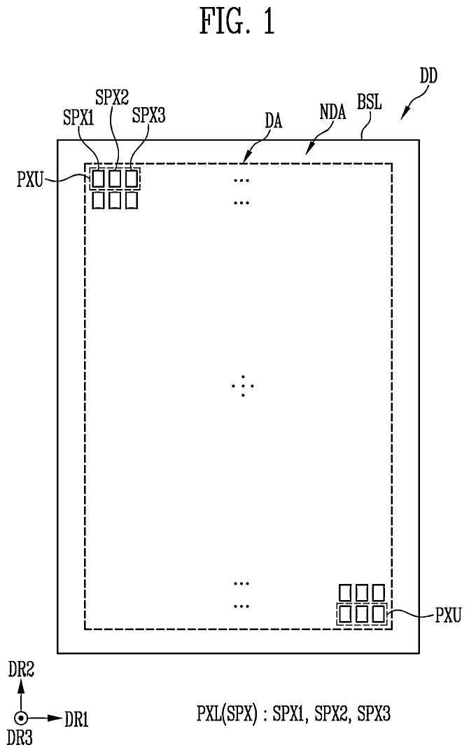

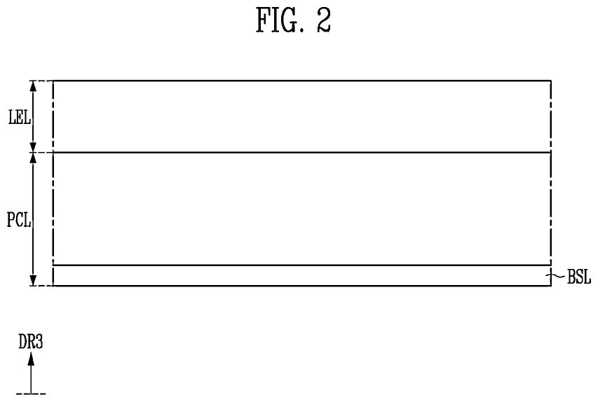

FIG. 1 is a plan view schematically illustrating a display device DD according to an embodiment. FIG. 2 is a cross-sectional view schematically illustrating the display device DD according to an embodiment.

Hereinafter, with reference to FIGS. 1 and 2, the display device DD according to an embodiment of the disclosure is schematically described.

Referring to FIG. 1, the display device DD is configured to emit light. The display device DD includes a light emitting element. According to an embodiment, the display device DD may be a device for displaying a moving image or a still image. The display device DD may be used as a display screen of various products such as not only a portable electronic device such as a mobile phone, a smart phone, a tablet personal computer (PC), a smart watch, a watch phone, a mobile communication terminal, an electronic notebook, an electronic book, a portable multimedia player (PMP), a navigation device, and an ultra mobile PC (UMPC), but also a television, a notebook computer, a monitor, a billboard, and Internet of things (IOT). However, an application field of the display device DD is not limited to a specific example.

The display device DD may be formed in a plane of a rectangular shape having a short side of a first direction DR1 and a long side of a second direction DR2 crossing the first direction DR1. A corner where the short side of the first direction DR1 and the long side of the second direction DR2 meet may be formed to be rounded to have a predetermined curvature or may be formed in a right angle. A planar shape of the display device DD is not limited to a quadrangle, and may be formed in another polygon or may be formed in a round shape such as a circle or an ellipse. The display device may be formed to be flat, but is not limited thereto. For example, the display device DD may include a curved portion formed at left and right ends and having a constant curvature or a varying curvature. In addition, the display device DD may be flexibly formed to be crooked, curved, bent, folded, or rolled.

In the disclosure, the first direction DR1 may be a row direction of a pixel PXL and may be a “horizontal” direction. The second direction DR2 may be a column direction of the pixel PXL. A third direction DR3 may be a display direction of the display device DD or a normal direction of a plane on which a base layer BSL is disposed.

The display device DD may include a display area DA and a non-display area NDA. The non-display area NDA may mean an area other than the display area DA. The non-display area NDA may surround at least a portion of the display area DA.

The display area DA may mean an area where the pixel PXL is disposed. The non-display area NDA may mean an area in which the pixel PXL is not disposed. A driving circuit unit, lines, and pads connected to the pixel PXL of the display area DA may be disposed in the non-display area NDA.

According to an embodiment, the pixel PXL (or sub-pixels SPX) may include a first sub-pixel SPX1, a second sub-pixel SPX2, and a third sub-pixel SPX3. At least one of the first sub-pixel SPX1, the second sub-pixel SPX2, and the third sub-pixel SPX3 may form one pixel unit PXU capable of emitting light of various colors. In FIG. 1, an embodiment in which each pixel PXL includes three sub-pixels SPX1, SPX2, and SPX3, that is, the first sub-pixel SPX1, the second sub-pixel SPX2, and the third sub-pixel SPX3 is exemplified, but an embodiment of the present specification is not limited thereto.

According to an embodiment, the pixels PXL (or the sub-pixels SPX) may be arranged according to a stripe or a PENTILE™ arrangement structure or the like. However, the disclosure is not necessarily limited thereto.

The first sub-pixel SPX1 may emit first light, the second sub-pixel SPX2 may emit second light, and the third sub-pixel SPX3 may emit third light. Here, the first light may be light of a red wavelength band, the second light may be light of a green wavelength band, and the third light may be light of a blue wavelength band. The red wavelength band may be a wavelength band of about 600 nm to 750 nm, the green wavelength band may be a wavelength band of about 480 nm to 560 nm, and the blue wavelength band may be a wavelength band of about 370 nm to 460 nm, but an embodiment of the present specification is not limited thereto.

Each of the first sub-pixel SPX1, the second sub-pixel SPX2, and the third sub-pixel SPX3 may include an inorganic light emitting element including an inorganic semiconductor or an organic light emitting element (organic light emitting diode (OLED)) as a light emitting element emitting light. However, the disclosure is not limited to a specific example.

Referring to FIG. 2, the display device DD may include a pixel circuit layer PCL and a light emitting element layer LEL.

The pixel circuit layer PCL may be a layer including a pixel circuit for driving light emitting elements. The pixel circuit layer PCL may include the base layer BSL, conductive layers for forming pixel circuits, and insulating layers disposed between the conductive layers.

The base layer BSL may form a base member of the display device DD. The base layer BSL may be a rigid or flexible substrate or film. For example, the base layer BSL may be a rigid substrate formed of glass or tempered glass, a flexible substrate (or thin film) of a plastic or metal material, or at least one insulating layer. According to an embodiment, the base layer BSL may include silicon (Si). A material and/or a physical property of the base layer BSL are/is not particularly limited. According to an embodiment, the base layer BSL may be substantially transparent. Here, “substantially transparent” may mean that light may be transmitted at one transmittance or more. In an embodiment, the base layer BSL may be translucent or opaque. In addition, the base layer BSL may include a reflective material according to an embodiment.

According to an embodiment, the pixel circuit may include a thin film transistor and may be electrically connected to the light emitting elements to provide an electrical signal for the light emitting elements to emit light.

The light emitting element layer LEL may be disposed on the pixel circuit layer PCL. The light emitting element included in the light emitting element layer LEL may include an inorganic light emitting element or an organic light emitting element. The light emitting element may be electrically connected to the pixel circuit included in the pixel circuit layer PCL.

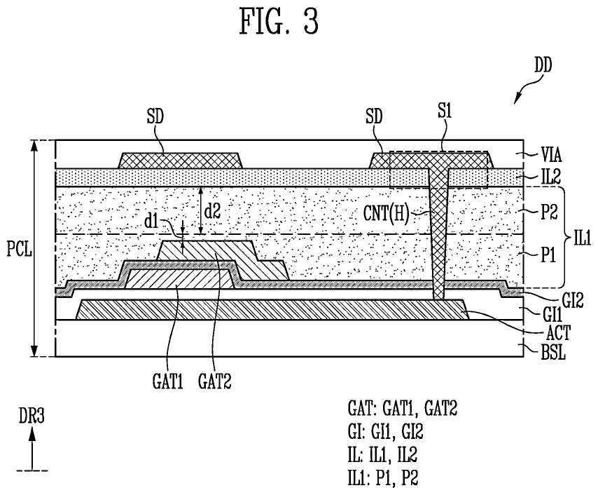

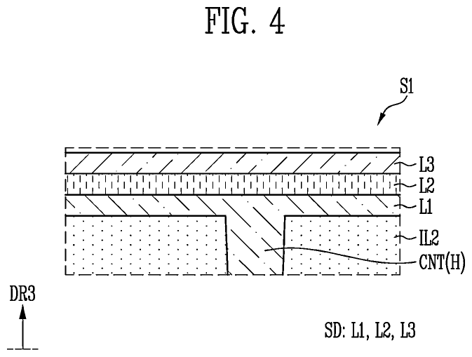

Hereinafter, a display device according to a first embodiment is described with reference to FIGS. 3 and 4.

FIG. 3 is a schematic cross-sectional view illustrating the display device DD according to the first embodiment. FIG. 3 may be a schematic diagram illustrating the pixel circuit layer PCL of the display device DD. FIG. 4 is a schematic cross-sectional view illustrating a disposition relationship between an interlayer conductive layer SD and a second insulating layer IL2. FIG. 4 is a schematic enlarged view illustrating an S1 area of FIG. 3, and may be a diagram illustrating an example of a stack structure of the interlayer conductive layer SD.

Referring to FIG. 3, the pixel circuit layer PCL may include the base layer BSL, an active layer ACT, a gate electrode GAT, a gate insulating layer GI, an insulating layer IL, the interlayer conductive layer SD, a contact hole CNT, and a via layer VIA.

The active layer ACT may be disposed on the base layer BSL. According to an embodiment, a buffer layer including an inorganic material may be disposed on the base layer BSL, and the active layer ACT may be disposed on the buffer layer.

According to an embodiment, the active layer ACT may include one or more of an oxide semiconductor, an inorganic semiconductor, and an organic semiconductor. According to an embodiment, the oxide semiconductor may include oxide including at least one of a group of indium (In), gallium (Ga), tin (Sn), zirconium (Zr), vanadium (V), hafnium (Hf), cadmium (Cd), germanium (Ge), chromium (Cr), titanium (Ti), and zinc (Zn). According to an embodiment, the inorganic semiconductor may include amorphous silicon, polycrystalline silicon, and the like. However, the disclosure is not limited thereto.

The active layer ACT may include a source area electrically connected to a source electrode, a drain area electrically connected to a drain electrode, and a channel area positioned between the source area and the drain area.

The active layer ACT may have a thickness of a range of 300 Å to 700 Å. However, the disclosure is not limited thereto. In the disclosure, a thickness of configurations of the display device described below is not limited to a numerical range described in the disclosure.

The gate insulating layer GI, the gate electrode GAT, and the insulating layer IL may be disposed on the active layer ACT. The gate insulating layer GI may include a first gate insulating layer GI1 and a second gate insulating layer GI2. The gate electrode GAT may include a first gate electrode GAT1 and a second gate electrode GAT2. The gate electrode GAT may be spaced apart from the active layer ACT. The insulating layer IL may include a first insulating layer IL1 and a second insulating layer IL2.

The first gate insulating layer GI1 may be disposed on the active layer ACT. The first gate insulating layer GI1 may be disposed between the active layer ACT and the first gate electrode GAT1. The first gate insulating layer GI1 may contact the active layer ACT. The first gate insulating layer GI1 may entirely cover the active layer ACT.

The first gate insulating layer GI1 may include an inorganic material. For example, the first gate insulating layer GI1 may include silicon oxide (SiOx). The first gate insulating layer GI1 may have a thickness thicker than a thickness of the active layer ACT. For example, the first gate insulating layer GI1 may have a thickness of a range of 800 Å to 1600 Å.

The first gate electrode GAT1 may be disposed on the first gate insulating layer GI1. The first gate electrode GAT1 may contact the first gate insulating layer GI1. The first gate electrode GAT1 may overlap at least a portion of the first gate insulating layer GI1 in a plan view.

The first gate electrode GAT1 may be formed as single layer or multiple layers formed of molybdenum (Mo), copper (Cu), aluminum (Al), chromium (Cr), gold (Au), titanium (Ti), nickel (Ni), neodymium (Nd), indium (In), tin (Sn), and an oxide or an alloy thereof.

The first gate electrode GAT1 may have a thickness of a range of 2000 Å to 3000 Å.

The second gate insulating layer GI2 may be disposed on the first gate electrode GAT1. The second gate insulating layer GI2 may contact the first gate electrode GAT1 and the first gate insulating layer GI1. The second gate insulating layer GI2 may entirely cover the first gate electrode GAT1 and the first gate insulating layer GI1.

The second gate insulating layer GI2 may include an inorganic material. The second gate insulating layer GI2 may include a material different from a material of the first gate insulating layer GI1. For example, the second gate insulating layer GI2 may include silicon nitride (SiNx). The second gate insulating layer GI2 may have a thickness thicker than a thickness of the active layer ACT. For example, the second gate insulating layer GI2 may have a thickness of range of 800 Å to 1600 Å.

The second gate electrode GAT2 may be disposed on the second gate insulating layer GI2. The second gate electrode GAT2 may contact the second gate insulating layer GI2. The second gate electrode GAT2 may overlap at least a portion of the second gate insulating layer GI2 in a plan view.

The second gate electrode GAT2 may be formed as a single layer or multiple layers formed of molybdenum (Mo), copper (Cu), aluminum (Al), chromium (Cr), gold (Au), titanium (Ti), nickel (Ni), neodymium (Nd), indium (In), tin (Sn), and an oxide or an alloy thereof.

The second gate electrode GAT2 may have a thickness of a range of 2000 Å to 3000 Å. However, the disclosure is not limited thereto.

The first insulating layer IL1 may be disposed on the second gate electrode GAT2. The first insulating layer IL1 may contact the second gate electrode GAT2 and the second gate insulating layer GI2. The first insulating layer IL1 may entirely cover the second gate electrode GAT2 and the second gate insulating layer GI2.

The first insulating layer IL1 may include a flat surface (for example, an upper surface). For example, as one surface of the first insulating layer IL1, an upper surface adjacent to the second insulating layer IL2 may be substantially flat. For example, one surface, for example, a surface that does not contact the second gate electrode GAT2, of the first insulating layer IL1 may be flat. One surface of the first insulating layer IL1 may not have a step difference.

The first insulating layer IL1 may include an inorganic material. For example, the first insulating layer IL1 may include silicon oxide (SiOx).

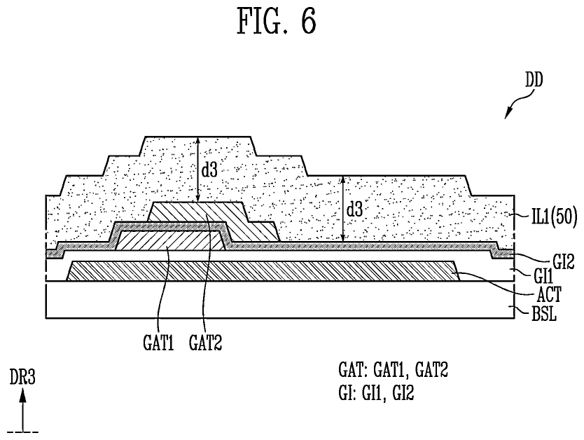

The first insulating layer IL1 may include a first insulating portion P1 and a second insulating portion P2. The first insulating portion P1 and the second insulating portion P2 may be portions including a same material, and may offset a step difference formed due to electrode pattern layers in the pixel circuit layer PCL. According to an embodiment, the first insulating portion P1 and the second insulating portion P2 may be formed in different processes. This is described later with reference to drawings after FIG. 6.

The first insulating portion P1 may have a first thickness d1. The first thickness d1 may be a thickness defined in a partial area of the first insulating layer IL1, and may be a thickness of the first insulating layer IL1 in an area simultaneously overlapping the first gate electrode GAT1 and the second gate electrode GAT2 in a plan view. According to an embodiment, the first thickness d1 may be 500 Å to 1000 Å.

The second insulating portion P2 may have a second thickness d2. The second thickness d2 may be a thickness defined in a partial area of the first insulating layer IL1, and may be a thickness of the first insulating layer IL1 in an area simultaneously overlapping the first gate electrode GAT1 and the second gate electrode GAT2 in a plan view. The second thickness d2 may be greater than the first thickness d1. According to an embodiment, the second thickness d2 may be 2500 Å to 4000 Å.

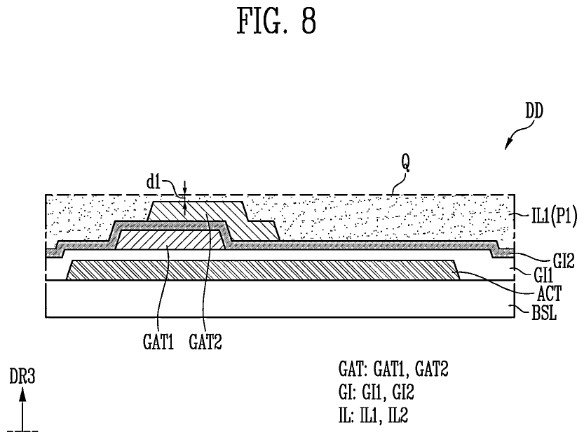

The second insulating portion P2 and the first insulating portion P1 may be defined based on a virtual surface. The virtual surface may be defined during a process procedure. The virtual surface may be a polish surface Q (refer to FIG. 8) formed by polishing the first insulating layer IL1. The virtual surface may be a flat surface. The virtual surface may be parallel to one surface (for example, an upper surface) of the second gate electrode GAT2.

The polish surface Q according to the first embodiment may be disposed on a plane different from one surface of the second gate electrode GAT2.

The second insulating layer IL2 may be disposed on the first insulating layer IL1. The second insulating layer IL2 may contact the first insulating layer IL1. The second insulating layer IL2 may entirely cover the first insulating layer IL1. The second insulating layer IL2 may include flat one surface and another surface. The second insulating layer IL2 may entirely contact the first insulating layer IL1. The second insulating layer IL2 may entirely overlap the first insulating layer IL1 in a plan view. One surface of the first insulating layer IL1 may face the second insulating layer IL2.

The second insulating layer IL2 may include an inorganic material. The second insulating layer IL2 may include an inorganic material different from an inorganic material of the first insulating layer IL1. For example, the second insulating layer IL2 may include silicon nitride (SINx). The second insulating layer IL2 may have a thickness of 1500 Å to 2500 Å.

The interlayer conductive layer SD may be disposed on the second insulating layer IL2. The interlayer conductive layer SD may contact the second insulating layer IL2. The interlayer conductive layer SD may overlap at least a portion of the second insulating layer IL2 in a plan view.

Since another surface of the second insulating layer IL2 is flat, the interlayer conductive layer SD disposed on the second insulating layer IL2 may include flat one surface, i.e., one surface that is flat. The interlayer conductive layer SD may include flat another surface, i.e., another surface that is flat. For example, a surface where the interlayer conductive layer SD and the second insulating layer IL2 contact may be flat. A surface of the interlayer conductive layer SD spaced apart from the second insulating layer IL2 may be flat.

Experimentally, when the interlayer conductive layer SD is deposited on a surface which is not flat, the interlayer conductive layer SD may be formed so that a thickness is non-uniform. Experimentally, when the thickness of the interlayer conductive layer SD is non-uniform, a line width roughness of the interlayer conductive layer SD may increase. On the other hand, since the interlayer conductive layer SD according to the disclosure is deposited on the flat second insulating layer IL2, the interlayer conductive layer SD may have a uniform thickness. The interlayer conductive layer SD may form a substantially uniform step difference. Accordingly, the interlayer conductive layer SD of the display device DD according to the disclosure may reduce the line width roughness.

The interlayer conductive layer SD may include a source electrode and a drain electrode. The interlayer conductive layer SD may be formed as single layer of multiple layers formed of molybdenum (Mo), copper (Cu), aluminum (Al), chromium (Cr), gold (Au), titanium (Ti), nickel (Ni), neodymium (Nd), indium (In), tin (Sn), and an oxide or an alloy thereof.

At least a portion of the interlayer conductive layer SD may be electrically connected to the active layer ACT through the contact hole CNT of the pixel circuit layer PCL. At least a portion of the interlayer conductive layer SD may be electrically connected to the active layer ACT through the contact hole CNT passing through the insulating layers IL1 and IL2.

The via layer VIA may be disposed on the interlayer conductive layer SD. The via layer VIA may entirely cover the interlayer conductive layer SD. The via layer VIA may contact the interlayer conductive layer SD.

The via layer VIA may include an organic material. For example, an organic material may include one or more of a group of acryl resin, epoxy resin, phenol resin, polyamide resin, polyimide resin, polyester resin, polyphenylenesulfide resin, and benzocyclobutene.

The display device DD according to an embodiment of the disclosure may include the pixel circuit layer PCL of which a stack thickness is reduced. As the stack thickness of the pixel circuit layer PCL is reduced, at etching depth of a hole H for forming the contact hole CNT of the pixel circuit layer PCL may be reduced. This is described later with reference to the drawings after FIG. 6.

Referring to FIG. 4, according to an embodiment, the interlayer conductive layer SD may have a multilayer structure including a first layer L1, a second layer L2, and a third layer L3.

The first layer L1 and the third layer L3 may include the same material. The first layer L1 and the third layer L3 may include a material different from a material of the second layer L2. For example, the first layer L1 may include titanium (Ti), the second layer L2 may include aluminum (Al), and the third layer L3 may include titanium (Ti).

However, the disclosure is not limited to the above-described example. Hereinafter, for convenience of description, the disclosure is described based on an embodiment in which the interlayer conductive layer SD includes the first layer L1 including titanium (Ti), the second layer L2 including aluminum (Al), and the third layer L3 including titanium (Ti).

The first layer L1 may contact the second insulating layer IL2. A lower surface of the first layer L1 may contact an upper surface of the second insulating layer IL2. The first layer L1 may be disposed in a hole H.

The second layer L2 may be spaced apart from the second insulating layer IL2. The second layer L2 may not contact the second insulating layer IL2. One surface (for example, an upper surface) of the second layer L2 may not contact the first layer L1. Another surface (for example, a lower surface) of the second layer L2 may contact the first layer L1. The second layer L2 may not be disposed in the hole H.

The third layer L3 may be spaced apart from the second insulating layer IL2. The third layer L3 may not contact the second insulating layer IL2. One surface (for example, an upper surface) of the third layer L3 may not contact the second layer L2. Another surface (for example, a lower surface) of the third layer L3 may contact the second layer L2. The third layer L3 may not be disposed in the hole H.

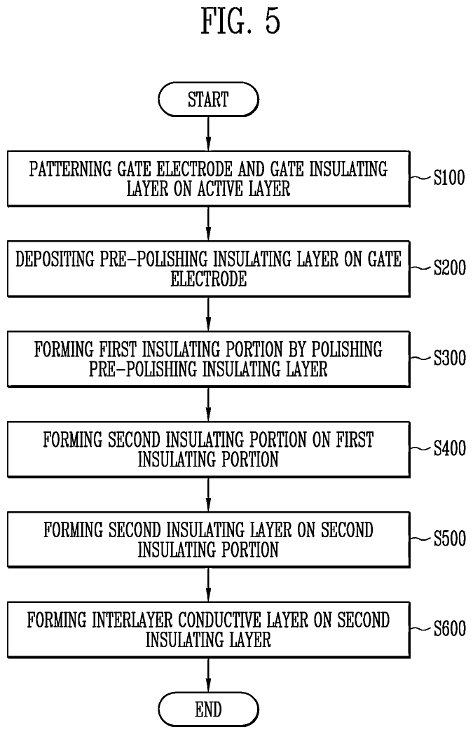

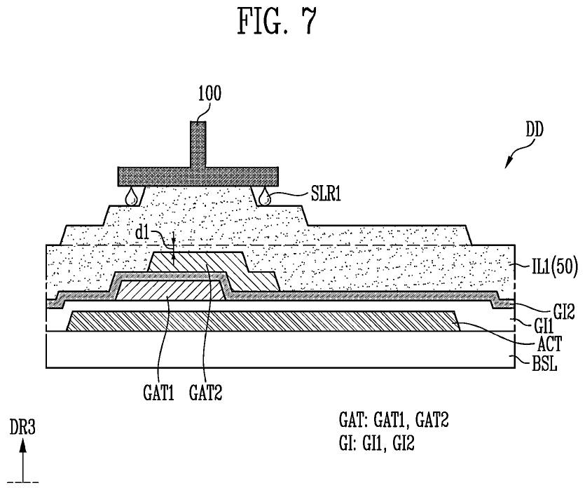

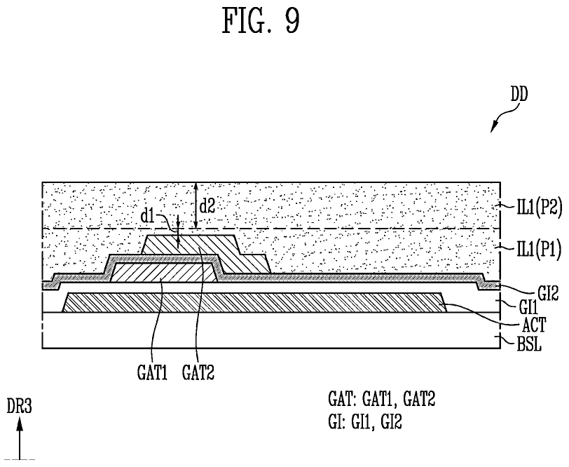

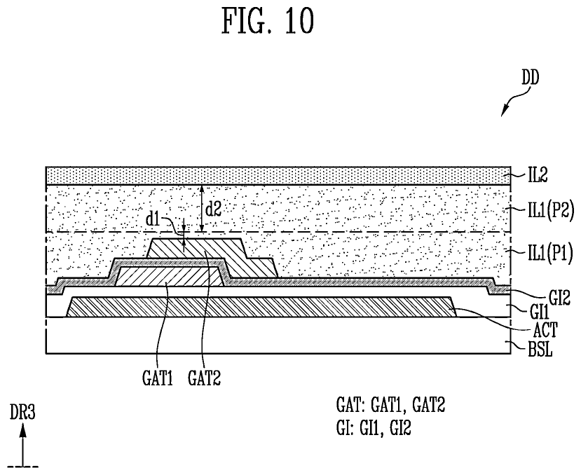

Hereinafter, a method of manufacturing the display device according to the first embodiment is described with reference to FIGS. 5 to 13. Contents overlapping the above-described contents are not repeated or are briefly described.

FIG. 5 is a flowchart illustrating a method of manufacturing a display device according to an embodiment. FIGS. 6 to 13 are schematic cross-sectional views for each manufacturing process operation of the display device according to the first embodiment. FIGS. 6 to 13 may be diagrams illustrating the pixel circuit layer PCL of the display device DD in more detail.

Referring to FIG. 5, the method of manufacturing the display device DD may include patterning the gate electrode and the gate insulating layer on the active layer in an operation S100, depositing a pre-polishing insulating layer on the gate electrode in an operation S200, forming the first insulating portion of the first insulating layer by polishing the pre-polishing insulating layer in an operation S300, forming the second insulating portion of the first insulating layer on the first insulating portion in an operation S400, forming the second insulating layer on the second insulating portion in an operation S500, and forming the interlayer conductive layer on the second insulating layer in an operation S600.

Referring to FIGS. 5 and 6, in patterning the gate electrode and the gate insulating layer on the active layer in the operation S100, the base layer BSL may be prepared. The active layer ACT may be patterned on the base layer BSL, and the gate electrode GAT and the gate insulating layer GI may be formed on the active layer ACT.

Forming the gate electrode GAT may include forming the first gate electrode GAT1 and the second gate electrode GAT2 spaced apart from the active layer ACT on the active layer ACT. Forming the gate insulating layer GI may include forming the first gate insulating layer GI1 and the second gate insulating layer GI2.

The first gate insulating layer GI1 may be formed on the active layer ACT. The first gate insulating layer GI1 may be deposited on the active layer ACT to entirely cover the active layer ACT. In an embodiment, one or more of a chemical vapor deposition (CVD) process and an atomic layer deposition (ALD) process may be used as a process for depositing a configuration of the display device DD. However, the embodiments are not limited to a specific example.

The first gate electrode GAT1 may be formed on the first gate insulating layer GI1. The first gate electrode GAT1 may be deposited on the first gate insulating layer GI1 and etched. In an embodiment, one or more of wet etching and dry etching may be used as a process for etching a configuration of the display device DD. However, the embodiments are not limited to a specific example.

The second gate insulating layer GI2 may be formed on the first gate electrode GAT1. The second gate insulating layer GI2 may be deposited to entirely cover the first gate electrode GAT1 and the first gate insulating layer GI1.

The second gate electrode GAT2 may be formed on the second gate insulating layer GI2. The second gate electrode GAT2 may be deposited on the second gate insulating layer GI2 and etched.

In depositing the pre-polishing insulating layer on the gate electrode in the operation S200, a pre-polishing insulating layer 50 may be deposited on the second gate electrode GAT2. The pre-polishing insulating layer 50 may be deposited to entirely cover the second gate electrode GAT2 and the second gate insulating layer GI2. The pre-polishing insulating layer 50 may be directly deposited on the second gate electrode GAT2. The pre-polishing insulating layer 50 may contact the second gate electrode GAT2.

The pre-polishing insulating layer 50 may be deposited on the second gate electrode GAT2 to have a substantially uniform pre-polishing thickness d3. The pre-polishing thickness d3 may correspond to a step difference between the active layer ACT and the second gate electrode GAT2. For example, the pre-polishing thickness d3 may be a distance from one, e.g., an upper, surface of the pre-polishing insulating layer 50 that does not contact the second gate insulating layer GI2 and one, e.g., an upper, surface of the second gate insulating layer GI2 that does not contact the first gate insulating layer GI1 in the third direction DR3. As another example, the pre-polishing thickness d3 may be a distance from the one, e.g., the upper, surface of the pre-polishing insulating layer 50 that does not contact the second gate electrode GAT2 and one, e.g., an upper, surface of the second gate electrode GAT2 that overlaps the first gate electrode GAT1 and does not contact the second gate insulating layer GI2 in the third direction DR3. According to an embodiment, the pre-polishing thickness d3 may be 5500 Å to 8250 Å.

The pre-polishing insulating layer 50 may be polished to form a portion (for example, the first insulating portion P1) of the first insulating layer IL1 (refer to FIG. 8). A portion of the pre-polishing insulating layer 50 may form a portion of the first insulating layer IL1. In the disclosure, the pre-polishing insulating layer 50 may be defined as the first insulating layer IL1 before a chemical mechanical polishing (CMP) process is performed.

The pre-polishing insulating layer 50 may include an inorganic material. The pre-polishing insulating layer 50 may include a same material as the first insulating layer IL1. For example, the pre-polishing insulating layer 50 may include silicon oxide (SiOx).

Referring to FIGS. 5, 7, and 8, in forming the first insulating portion of the first insulating layer by polishing the pre-polishing insulating layer in the operation S300, the pre-polishing insulating layer 50 may be polished by a polishing device 100 and a first slurry SLR1.

The polishing device 100 may determine a polishing end point of a polishing process by adjusting a polishing time or the like. The first slurry SLR1 may assist polishing of the polishing device 100. For example, the first slurry SLR1 may include an abrasive particle, and generate friction when the abrasive particle contacts the configurations of the display device DD to mechanically polish the configuration of the display device DD. Alternatively, the abrasive particle may cause a chemical reaction with some of the configurations of the display device DD to polish the configuration of the display device DD.

The pre-polishing insulating layer 50 may be polished to have a first thickness d1 in a partial area (for example, an area simultaneously overlapping the first gate electrode GAT1 and the second gate electrode GAT2). The first thickness d1 may be 500 Å to 1000 Å. The pre-polishing insulating layer 50 may be polished to form the flat polish surface Q. The pre-polishing insulating layer 50 may be planarized. The polish surface Q may be spaced apart from the second gate electrode GAT2.

The pre-polishing insulating layer 50 may be polished to form the first insulating portion P1 of the first insulating layer IL1. In the display device DD according to an embodiment of the disclosure, the pre-polishing insulating layer 50 may be directly disposed on the second gate electrode GAT2, and a configuration (for example, the pre-polishing insulating layer 50) directly disposed on the second gate electrode GAT2 may be polished.

In a conventional display structure, additional insulating layers that are not polished are disposed directly on the second gate electrode GAT2, and a pre-polishing insulating layer 50, which is an object on which a polishing process is performed is disposed on the insulating layers that are not polished. Accordingly, a thickness of the pixel circuit layer PCL is increased, and the etching depth for forming the hole H in the pixel circuit layer PCL is increased.

In addition, in the conventional display structure, insulating layers disposed under the pre-polishing insulating layer 50 are formed at the outermost portion to determine the end point of the polishing process of the polishing device 100, and include a polishing auxiliary layer including silicon nitride (SiNx). For example, a polishing slurry used in manufacturing a conventional display has a selectivity to a layer including silicon oxide (SiOx) higher than to a layer including silicon nitride (SINx). When the pre-polishing insulating layer 50 including silicon oxide (SiOx) is polished and then the polishing auxiliary layer including silicon nitride (SiNx) is exposed, a change in frictional force caused by the polishing slurry is sensed by the polishing device 100 or an interference shape of a wavelength according to a change in a thickness of a film on which the polishing process is performed is sensed by an optical sensor that may be included in the polishing device 100. At this point, the polishing is stopped. For example, when the pre-polishing insulating layer 50 is polished and then the polishing auxiliary layer including silicon nitride (SINx) is exposed, the frictional force applied to the polishing device 100 increases. Accordingly, when a current for driving the polishing device 100 is increased, a change in current is sensed, and thus polishing is stopped. In addition, for example, when the polishing device 100 further includes an optical sensor, the optical sensor senses an interference shape of a reflective wavelength according to a change in thickness between the polishing auxiliary layer including silicon nitride (SiNx) and the pre-polishing insulating layer 50, and thus polishing is stopped.

In order to stop polishing when the polishing auxiliary layer including silicon nitride (SiNx) is exposed, the conventional polishing slurry is provided as a functional slurry having a relatively high selectivity to silicon oxide (SiOx) compared to silicon nitride (SINx). The functional slurry has a selectivity of 1:30 to 1:50 based on silicon nitride (SiNx):silicon oxide (SiOx).

In the display device DD according to an embodiment of the disclosure, the pre-polishing insulating layer 50 may be directly disposed on the second gate electrode GAT2, and the polishing auxiliary layer may not be disposed between the second gate electrode GAT2 and the pre-polishing insulating layer 50. Since the polishing auxiliary layer is not disposed, the pre-polishing insulating layer 50 may be polished by adjusting the polishing time or the like of the polishing device 100. For example, the pre-polishing insulating layer 50 may be polished during a predetermined polishing time.

In addition, since the polishing auxiliary layer is not disposed under the pre-polishing insulating layer 50, a first slurry SLR1 used when manufacturing the display device DD according to an embodiment of the disclosure may not be provided as the functional slurry. For example, a selectivity to a material other than silicon oxide (SiOx) of the first slurry SLR1 may not be considered. The first slurry SLR1 may polish a large amount of silicon oxide (SiOx), and may polish a large amount or a small amount of silicon nitride (SiNx). Since the selectivity of the first slurry SLR1 to the material other than silicon oxide (SiOx) is not considered, the polishing device 100 may not require an additional time for sensing the change in frictional force, thereby reducing a polishing process time.

According to an embodiment, the first slurry SLR1 may include one or more of a group of ceria (CeO2) and silica (SiO2). However, the disclosure is not limited thereto.

Referring to FIGS. 5, 9, and 10, in forming the second insulating portion of the first insulating layer on the first insulating portion in the operation S400, the second insulating portion P2 of the first insulating layer IL1 may be deposited on the first insulating portion P1 of the first insulating layer IL1.

As the second insulating portion P2 of the first insulating layer IL1 is further deposited, the first insulating layer IL1 may separate the second gate electrode GAT2 and the interlayer conductive layer SD to be deposited later by an appropriate distance, and may insulate the second gate electrode GAT2 from the interlayer conductive layer SD. When the second insulating portion P2 is not further deposited, a distance between the second gate electrode GAT2 and the interlayer conductive layer SD may be excessively close, and the second gate electrode GAT2 and the interlayer conductive layer SD may not be insulated.

As the second insulating portion P2 is deposited after the pre-polishing insulating layer 50 is planarized to form the first insulating portion P1, the second insulating portion P2 may include a flat surface. For example, one surface of the second insulating portion P2 (for example, an upper surface or a surface that does not contact the first insulating portion P1) and another surface (for example, a lower surface or a surface contacting the first insulating portion P1) may be flat.

The second insulating portion P2 may be deposited to have a substantially uniform second thickness d2. The second thickness d2 may be thicker than the first thickness d1. For example, the second thickness d2 may be 2500 Å to 4000 Å. As the second thickness d2 is thicker than the first thickness d1, the second gate electrode GAT2 and the interlayer conductive layer SD may be separated by an appropriate distance, and the second gate electrode GAT2 and the interlayer conductive layer SD may be insulated.

In forming the second insulating layer on the second insulating portion in the operation S500, the second insulating layer IL2 may be formed on the second insulating portion P2 of the first insulating layer IL1. The second insulating layer IL2 may be deposited on the second insulating portion P2 of the first insulating layer IL1. The second insulating layer IL2 may entirely cover the second insulating portion P2.

As the second insulating portion P2 includes a flat surface, the second insulating layer IL2 deposited on the second insulating portion P2 may also include a flat surface. For example, one surface of the second insulating layer IL2 (for example, an upper surface or a surface that does not contact the first insulating layer IL1) and another surface (for example, a lower surface or a surface contacting the first insulating layer IL1) may be flat.

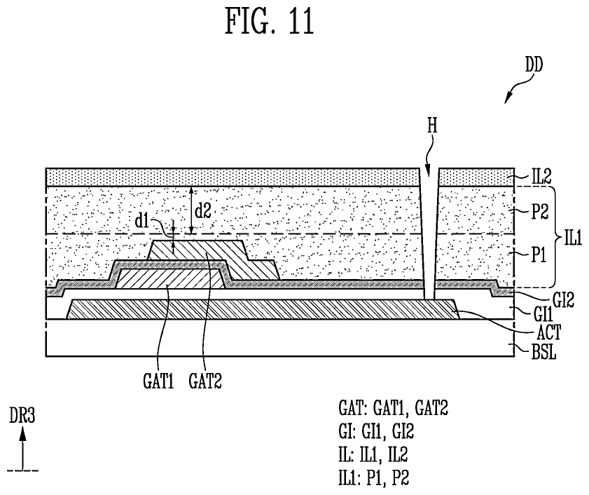

Referring to FIG. 11, in forming the interlayer conductive layer on the second insulating layer in the operation S600, the hole H may be formed. The hole H may be formed by etching at least a portion of the pixel circuit layer PCL. The hole H may be formed to pass through the second insulating layer IL2, the first insulating layer IL1, the second gate insulating layer GI2, and the first gate insulating layer GI1. At least a portion of the second insulating layer IL2, the first insulating layer IL1, the second gate insulating layer GI2, and the first gate insulating layer GI1 may be etched. A depth of the hole H may be a same as a distance from an upper surface of the active layer ACT to an upper surface of the second insulating layer IL2. Therefore, as a thickness of the pixel circuit layer PCL increases, the depth of the hole H may increase. As the depth of the hole H increases, necessity to further etch the pixel circuit layer PCL may increase.

In accordance with the display device DD according to the disclosure, the pre-polishing insulating layer 50 may be directly disposed on the second gate electrode GAT2, and the pixel circuit layer PCL of which the stack thickness is reduced may be provided. As the thickness of the pixel circuit layer PCL is reduced, necessity to deeply etch the pixel circuit layer PCL to form the hole H may be reduced. Accordingly, the hole H may be formed up to an area intended to appropriately expose the active layer ACT, and the hole H may be connected to the exposed active layer ACT.

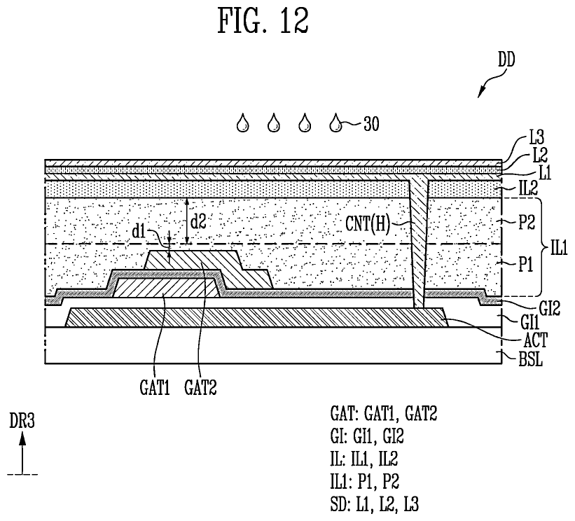

Referring to FIGS. 5 and 12, in forming the interlayer conductive layer on the second insulating layer in the operation S600, after the hole H is formed, the interlayer conductive layer SD may be formed. The interlayer conductive layer SD may be stably electrically connected to the active layer ACT through the contact hole CNT.

The interlayer conductive layer SD may include the first layer 7L1, the second layer L2, and the third layer L3. The first layer L1 and the third layer L3 may include the same material, and the first layer L1 and the third layer L3 may include a material different from a material of the second layer L2. For example, the first layer L1 may include titanium (Ti), the second layer L2 may include aluminum (Al), and the third layer L3 may include titanium (Ti). The first layer L1 may be deposited on the second insulating layer IL2, the second layer L2 may be deposited on the first layer L1, and the third layer L3 may be deposited on the second layer L2.

The interlayer conductive layer SD may be etched using an etching solution 30. According to an embodiment, the etching solution 30 may include chlorine radical (CI radical). Experimentally, the etching solution 30 including chlorine radical may be more consumed when reacting with silicon nitride (SiNx) rather than silicon oxide (SiOx). When the etching solution 30 is not consumed, etching may be excessive performed.

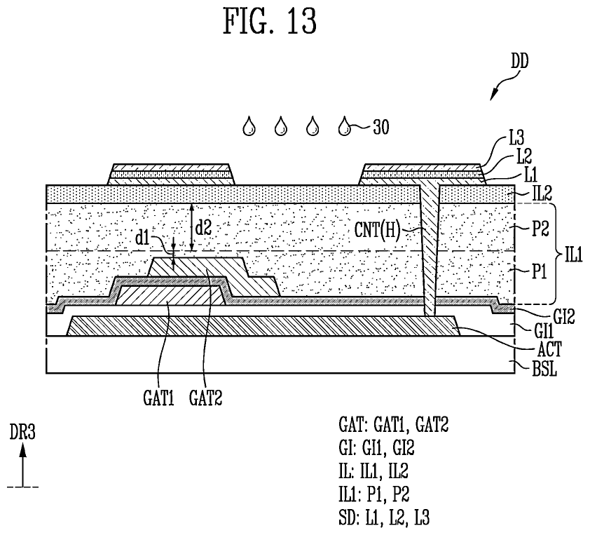

For example, referring to FIG. 13, the interlayer conductive layer SD may be etched to expose the second insulating layer IL2, and at this time, when a layer including silicon oxide (SiOx) is directly disposed under the first layer L1, the etching solution 30 may not be consumed, and the etching solution 30 may remain on the layer including silicon oxide (SiOx). The remaining etching solution 30 may splash to a side of the second layer L2 and excessively etch the second layer L2 including aluminum (Al).

In the display device DD according to an embodiment of the disclosure, a silicon nitride layer (SiNx) may be directly disposed under the first layer L1. Therefore, the etching solution 30 may be consumed, and the second layer L2 may not be excessively etched.

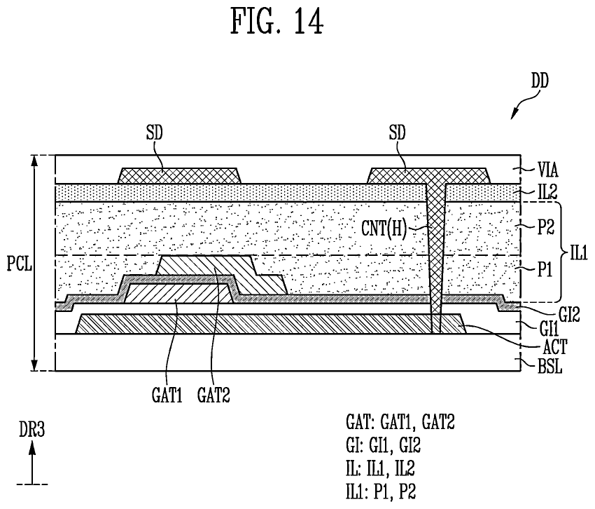

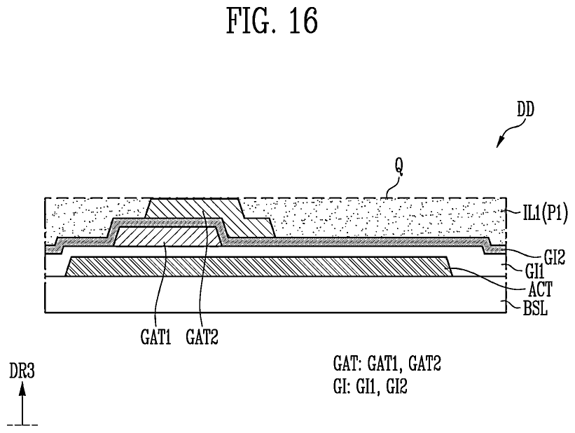

Hereinafter, a display device and a method of manufacturing a display device according to a second embodiment is described with reference to FIGS. 14 to 17 together with FIG. 5. Contents overlapping the above-described contents are not be repeated.

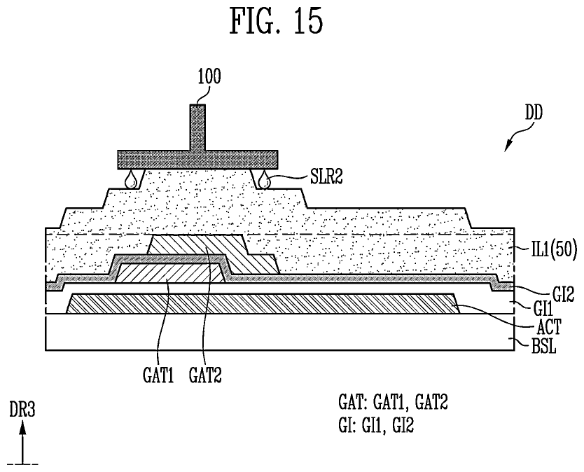

FIG. 14 is a schematic cross-sectional view of a display device DD according to the second embodiment. FIGS. 15 to 17 are schematic cross-sectional views for each manufacturing process operation of the display device DD according to the second embodiment. FIGS. 15 to 17 may be diagrams illustrating the pixel circuit layer PCL of the display device DD in more detail.

The second embodiment is different from the first embodiment, in that the pre-polishing insulating layer 50 is etched until the second gate electrode GAT2 is exposed when forming the first insulating portion P1 by etching the pre-polishing insulating layer 50.

Referring to FIG. 14, the first insulating portion P1 of the display device DD according to the second embodiment may not entirely cover the second gate electrode GAT2. For example, the first insulating portion P1 may cover a side surface of the second gate electrode GAT2 and may not cover an upper surface. The first insulating portion P1 may expose one surface (for example, the upper surface) of the second gate electrode GAT2 so that the one surface contacts another configuration of the display device DD.

The first insulating portion P1 may have a same step difference as the second gate electrode GAT2. One surface (for example, an upper surface) of the first insulating portion P1 and one surface (for example, the upper surface) of the second gate electrode GAT2 may be disposed on the same plane.

The second insulating portion P2 may contact at least a portion of the second gate electrode GAT2. The second insulating portion P2 may contact one surface of the second gate electrode GAT2.

Referring to FIGS. 5, 15 and 16, in forming the first insulating portion of the first insulating layer by polishing the pre-polishing insulating layer according to the second embodiment in the operation S300, the pre-polishing insulating layer 50 may be polished by the polishing device 100 and a second slurry SLR2.

The second slurry SLR2 may include one or more of a group of zirconia (ZrO2) and ceria (CeO2). The second slurry SLR2 may have a relatively high selectivity to an inorganic material compared to a metal. The second slurry SLR2 may have a high selectivity to the first insulating layer IL1 compared to the second gate electrode GAT2. For example, the second slurry SLR2 may have a relatively high selectivity to silicon oxide SiOx. For example, the second slurry SLR2 may have a selectivity of 1:30 to 1:50 based on the second gate electrode GAT2:silicon oxide (SiOx).

The pre-polishing insulating layer 50 may be polished by the polishing device 100 and the second slurry SLR2 to form the first insulating portion P1 of the first insulating layer IL1. The first insulating portion P1 may form the flat polish surface Q. The polish surface Q may be disposed on the same plane as one surface (for example, the upper surface) of the second gate electrode GAT2.

The pre-polishing insulating layer 50 may be polished to expose one surface (for example, the upper surface) of the second gate electrode GAT2. The pre-polishing insulating layer 50 may be polished to form the first insulating portion P1 so that the second gate electrode GAT2 and the first insulating portion P1 have the same step difference. The first insulating portion P1 may not be formed in an area where the first gate electrode GAT1 and the second gate electrode GAT2 overlap.

As the second slurry SLR2 has a relatively high selectivity silicon oxide (SiOx) compared to metal, the pre-polishing insulating layer 50 may be polished, and then polishing may be stopped when the second gate electrode GAT2 is exposed.

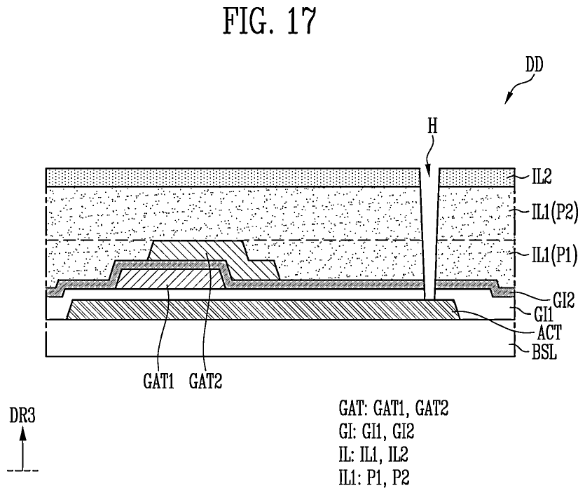

Referring to FIG. 17, after forming the first insulating portion P1, the second insulating portion P2 may be formed on the polished first insulating portion P1. After forming the second insulating portion P2, the second insulating layer IL2 may be formed. After forming the second insulating layer IL2, the hole H for electrically connecting the interlayer conductive layer SD and the active layer ACT may be formed.

As the pre-polishing insulating layer 50 is polished to expose the second gate electrode GAT2, in the display device DD according to the second embodiment, the pixel circuit layer PCL may have a thickness less than that of a case where the pre-polishing insulating layer 50 is polished so that the gate electrode GAT2 is not exposed. Accordingly, the etching depth of the pixel circuit layer PCL for forming the hole H may be reduced.

As described above, although the disclosure has been described with reference to the embodiment above, those skilled in the art or those having a common knowledge in the art will understand that the disclosure may be variously modified and changed without departing from the spirit and technical area of the disclosure described in the claims which will be described later.

Therefore, the technical scope of the disclosure should not be limited to the contents described in the detailed description of the specification, but should be defined by the claims.

What is claimed is:

1. A display device comprising:
an active layer;
a gate electrode disposed on the active layer;
a first insulating layer disposed on the gate electrode, entirely covering the gate electrode, and including a flat surface; and
a second insulating layer disposed on the first insulating layer and including a flat surface,
wherein the first insulating layer and the second insulating layer include inorganic materials different from each other.

2. The display device according to claim 1, wherein the active layer and the gate electrode are spaced apart from each other,
the display device further comprises a first gate insulating layer and a second gate insulating layer disposed on the active layer, and
the gate electrode includes a first gate electrode disposed on the first gate insulating layer and a second gate electrode disposed on the second gate insulating layer.

3. The display device according to claim 2, wherein the flat surface of the first insulating layer does not have a step difference.

4. The display device according to claim 3, wherein the flat surface of the first insulating layer faces the second insulating layer.

5. The display device according to claim 3, wherein the first insulating layer is directly disposed on the second gate electrode.

6. The display device according to claim 3, wherein the flat surface of the first insulating layer does not contact the second gate electrode.

7. The display device according to claim 5, wherein the first insulating layer includes silicon oxide, and
the second insulating layer includes silicon nitride.

8. The display device according to claim 1, further comprising:
an interlayer conductive layer disposed on the second insulating layer,
wherein one surface and another surface of the interlayer conductive layer are flat.

9. The display device according to claim 8, wherein the interlayer conductive layer comprises:
a first layer;
a second layer disposed on the first layer; and
a third layer disposed on the second layer, and
the first layer contacts the second insulating layer.

10. The display device according to claim 9, wherein the first layer and the third layer include a same material,
the second layer includes a material different from the material of the first layer and the third layer, and
the second layer includes aluminum.

11. A method of manufacturing a display device, the method comprising:
patterning an active layer on a base layer;
patterning a gate electrode on the active layer;
depositing a pre-polishing insulating layer on the gate electrode;
polishing the pre-polishing insulating layer to form a first insulating portion; and
forming a second insulating portion on the first insulating portion,
wherein the first insulating portion and the second insulating portion form a first insulating layer,
wherein the patterning the gate electrode on the active layer comprises:
forming a first gate electrode; and
forming a second gate electrode on the first gate electrode,
wherein the first gate electrode and the second gate electrode are spaced apart from the active layer, and
wherein in the depositing the pre-polishing insulating layer on the gate electrode, the pre-polishing insulating layer contacts the second gate electrode.

12. The method according to claim 11, wherein in the polishing the pre-polishing insulating layer to form the first insulating portion, the pre-polishing insulating layer is polished using a polishing device using a slurry, and
the first insulating portion forms a flat polish surface.

13. The method according to claim 12, further comprising:
forming a second insulating layer on the second insulating portion; and
forming an interlayer conductive layer on the second insulating layer,
wherein in the forming the interlayer conductive layer on the second insulating layer, the interlayer conductive layer is etched by an etching solution including a chlorine radical.

14. The method according to claim 13, wherein in the depositing the pre-polishing insulating layer on the gate electrode, the pre-polishing insulating layer is deposited to have a thickness of 5500 Å to 8250 Å.

15. The method according to claim 12, wherein in the polishing the pre-polishing insulating layer to form the first insulating portion, the pre-polishing insulating layer is polished to form the flat polish surface, and
the flat polish surface is disposed on a plane different from one surface of the second gate electrode.

16. The method according to claim 15, wherein the slurry includes silica, and
the pre-polishing insulating layer is polished during a predetermined polishing time.

17. The method according to claim 16, wherein in the polishing the pre-polishing insulating layer to form the first insulating portion, the first insulating portion is polished to have a thickness of 500 Å to 1000 Å in an area overlapping the first gate electrode and the second gate electrode.

18. The method according to claim 12, wherein in the polishing the pre-polishing insulating layer to form the first insulating portion, the pre-polishing insulating layer is polished to form the flat polish surface, and
the flat polish surface is disposed on a same plane as one surface of the second gate electrode.

19. The method according to claim 18, wherein the slurry Includes ceria.

20. The method according to claim 19, wherein the first Insulating layer includes silicon oxide, and
the slurry has a selectivity of 1:30 to 1:50 based on the second gate electrode: the silicon oxide.
